(19) United States
(12) Patent Application Publication
(10) Pub. No.: US 2009/0068777 A1
(43) Pub. Date: Mar. 12, 2009

(54) METHOD FOR MANUFACTURING PIXEL STRUCTURE

(75) Inventors: Shiun-Chang Jan, Hsinchu (TW); Chih-Chun Yang, Hsinchu (TW); Ming-Yuan Huang, Hsinchu (TW); Han-Tu Lin, Hsinchu (TW); Chih-Hung Shih, Hsinchu (TW); Ta-Wen Liao, Hsinchu (TW); Chia-Chi Tsai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/121,777

(22) Filed: May 15, 2008

(30) Foreign Application Priority Data
Sep. 11, 2007 (TW) 96133816

(51) Int. Cl. H01L 21/00

(52) U.S. Cl. 438/30; 257/E21.001

(57) ABSTRACT

A method for manufacturing a pixel structure is provided. First, a substrate with a gate formed thereon is provided. Next, a gate dielectric layer covering the gate is formed on the substrate. Then, a channel layer, a source and a drain are formed on the gate dielectric layer over the gate. The source and the drain are disposed on a portion of the channel layer. The gate, the channel layer, the source and the drain constitute a thin film transistor. Then, a passivation layer is formed on the gate dielectric layer and the thin film transistor. After that, a laser beam is utilized to irradiate the passivation layer via a first shadow mask so as to remove a portion of the passivation layer for exposing the drain. Then, a pixel electrode is formed on the gate dielectric layer and connected to the exposed drain.

### CROSS-REFERENCE TO RELATED APPLICATION

This application claims the priority benefit of Taiwan application serial no. 96133816, filed on Sep. 11, 2007. The entirety of the above-mentioned patent application is hereby incorporated by reference herein and made a part of specification.

### BACKGROUND OF THE INVENTION

1. Field of the Invention

The present invention relates to a method for manufacturing a pixel structure, and in particular, to a method for manufacturing a pixel structure having a passivation layer formed by a laser ablation process.

2. Description of Related Art

A display serves as a communication interface for humans to acquire information from a device, and the flat panel display (FPD) is the current trend in the display market. The FPD is mainly classified into an organic electroluminescence display, a plasma display panel (PDP), a thin film transistor liquid crystal display (TFT-LCD), and so forth, wherein the application of the TFT-LCD is most extensive. Generally, the TFT-LCD is mainly constituted by a thin film transistor array substrate (TFT array substrate), a color filter substrate and a liquid crystal layer. The TFT array substrate includes a plurality of scan lines, a plurality of data lines, and a plurality of pixel units arranged in an array. Each of the pixel structures is connected with the corresponding scan line and the data line respectively.

FIGS. 1A to 1G illustrate a process flow of manufacturing a prior art pixel structure. Referring to FIG. 1A first, a substrate 10 is provided, and a gate 20 is formed on the substrate 10 by performing a first photolithography and etching process (PEP). Next, referring to FIG. 1B, a gate insulating layer 30 is formed on the substrate 10 to cover the gate 20. Then, referring to FIG. 1C, a channel layer 40 is formed on the gate insulating layer 30 over the gate 20 by performing a second PEP. Generally, a material of the channel layer 40 is amorphous silicon. After that, referring to FIG. 1D, a source 50 and a drain 60 are formed on a portion of the channel layer 40 and a portion of the gate insulating layer 30 by performing a third PEP. As shown in FIG. 1D, the source 50 and the drain 60 extend to the gate insulating layer 30 from two sides of the channel layer 40 respectively and expose a portion of the channel layer 40. Thereafter, referring to FIG. 1E, a passivation layer 70 is then formed over the substrate 10 to cover the gate insulating layer 30, the channel layer 40, the source 50 and the drain 60. Afterwards, referring to FIG. 1F, the passivation layer 70 is patterned by performing a fourth PEP to form a contact hole H in the passivation layer. As shown in FIG. 1F, a portion of the drain 60 is exposed by the contact hole H in the passivation layer 70. Then, referring to FIG. 1G, a pixel electrode 80 is formed on the passivation layer 70 by performing a fifth PEP. As shown in FIG. 1G, the pixel electrode 80 is electrically connected with the drain 60 through the contact hole H. After the pixel electrode 80 is fabricated, the pixel structure 90 is substantially completed.

In light of the above, the prior art pixel structure 90 is mainly manufactured by performing five PEPs. In other words, the pixel structure 90 has to be manufactured by using five photo-masks respectively having a pattern different from one another. Since the cost for manufacturing the photo-masks is quite expensive, and each of the PEPs requires a photo-mask with a different pattern, the cost can not be reduced if the number of the PEPs can not be reduced.

Furthermore, as the size of the TFT LCD panel continuously increases, the size of the TFT array substrate increases accordingly, and thus a larger photo-mask has to be employed to fabricate the TFT array substrate. Because the cost of manufacturing the larger photo-mask is more expensive, the cost of manufacturing the pixel structure 90 can not be effectively reduced.

### SUMMARY OF THE INVENTION

The present invention relates to a method for manufacturing a pixel structure capable of reducing process cost.

As embodied and broadly described herein, a method for manufacturing a pixel structure is provided. The method includes providing a substrate at first and forming a gate on the substrate. Then, a gate dielectric layer is formed on the substrate to cover the gate. Next, a channel layer, a source and a drain are formed on the gate dielectric layer over the gate, wherein the source and the drain are disposed on a portion of the channel layer, and the gate, the channel layer, the source and the drain constitute a thin film transistor. After that, a passivation layer is formed on the gate dielectric layer and the thin film transistor. Thereafter, a laser beam is utilized to irradiate the passivation layer via a first shadow mask to remove a portion of the passivation layer for exposing the drain. Afterwards, a pixel electrode is formed on the gate dielectric layer. The pixel electrode is connected with the exposed drain.

According to one embodiment of the present invention, in the method for manufacturing the pixel structure, a method of forming the gate includes, for example, forming a first metal layer on the substrate at first. Then, the first metal layer is patterned to form the gate. According to another embodiment of the present invention, a method of forming the gate includes, for example, forming a first metal layer on the substrate at first. Next, a second shadow mask is provided over the first metal layer. The second shadow mask exposes a portion of the first metal layer. After that, the first metal layer is utilized to irradiate the first metal layer via the second shadow mask for removing the portion of the first metal layer exposed by the second shadow mask.

According to one embodiment of the present invention, in the method for manufacturing the pixel structure, a method of forming the channel layer, the source and the drain includes forming a semiconductor layer on the gate dielectric layer. Then, a second metal layer is formed on the semiconductor layer. Next, a photoresist layer is formed on the second metal layer over the gate. The photoresist layer comprises a first photoresist block and a second photoresist block connected with the first photoresist block. A thickness of the first photoresist block is less than a thickness of the second photoresist block. After that, a first etching process is performed on the second metal layer and the semiconductor layer by using the photoresist layer as a mask. Afterwards, the thickness of the photoresist layer is reduced until the first photoresist block is removed completely. Finally, a second etching process is performed on the second metal layer by using the remained second photoresist block as the mask, such that the remained second metal layer constitutes the source and the drain while the semiconductor layer constitutes the channel layer. According to other embodiments of the present invention, a method of forming the channel layer, the source and the drain further includes forming an ohmic contact layer on a surface of the semiconductor layer after the semiconductor layer is formed. Then, the ohmic contact layer uncovered by the second photoresist block is removed by performing the first etching process and the second etching process. Moreover, a method of reducing the thickness of the photoresist layer includes performing an ashing process.

According to one embodiment of the present invention, in the method for manufacturing the pixel structure, a method of forming the pixel electrode includes, for example, forming a conductive layer on the passivation layer and the thin film transistor after the portion of the passivation layer exposed by the first shadow mask is removed. Then, the conductive layer is patterned. According to another embodiment of the present invention, a method of forming the pixel electrode includes forming a conductive layer on the passivation layer and the thin film transistor after the portion of the passivation layer exposed by the first shadow mask is removed. Next, a third shadow mask is provided over the conductive layer. The third shadow mask exposes a portion of the conductive layer. After that, the laser beam is utilized to irradiate the conductive layer via the third shadow mask for removing the portion of the conductive layer exposed by the third shadow mask. According to other embodiments of the present invention, a method of forming the pixel electrode can includes forming a photoresist layer on the passivation layer after the portion of the passivation layer exposed by the first shadow mask is removed, wherein the photoresist layer exposes a portion of the drain. Then, a conductive layer is formed to cover the passivation layer, the drain, and the photoresist layer. After that, the photoresist layer is removed, so as to remove the conductive layer on the photoresist layer together. A method of forming the conductive layer includes forming an indium tin oxide (ITO) layer or an indium zinc oxide (IZO) layer by performing a sputtering process.

According to one embodiment of the present invention, in the method for manufacturing the pixel structure, an energy of the laser beam ranges from 10 mJ/cm² to 500 mJ/cm², for example. Furthermore, a wavelength of the laser beam ranges from 100 nm to 400 nm, for example.

In the present invention, the passivation layer is manufactured by performing a laser ablation process, so that the total photo-mask for the channel layer, the source and the drain can be manufactured reduced. Therefore, compared with a conventional method for manufacturing the pixel structure, the manufacturing process is simplified and the process cost of manufacturing photo-masks is reduced. Moreover, compared with a conventional photo-mask, the shadow mask used in the laser ablation process to manufacture the passivation is simplified. Therefore, the process cost of manufacturing the shadow mask used in the laser ablation process is lower.

In order to make the aforementioned and other objects, features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1G illustrate a process flow of manufacturing a prior art pixel structure.

FIGS. 2A to 2G are schematic views illustrating a method for manufacturing a pixel structure according to one embodiment of the present invention.

FIGS. 3A to 3C are schematic views illustrating a laser ablation process used for forming a gate.

FIGS. 4A to 4C are schematic views illustrating a laser ablation process used for forming a pixel electrode.

FIGS. 5A to 5C are schematic views illustrating another method of forming the pixel electrode.

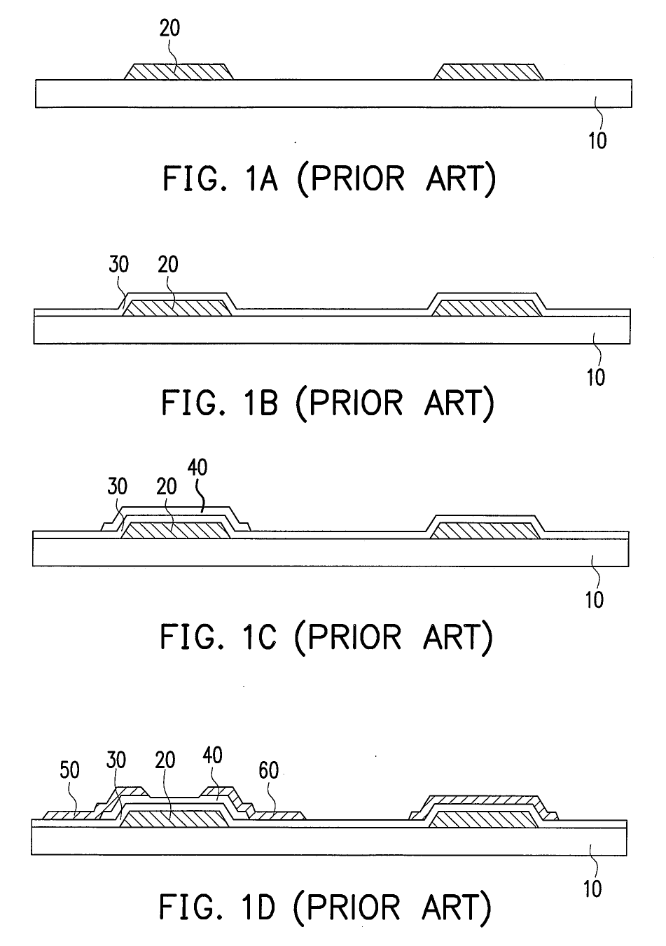

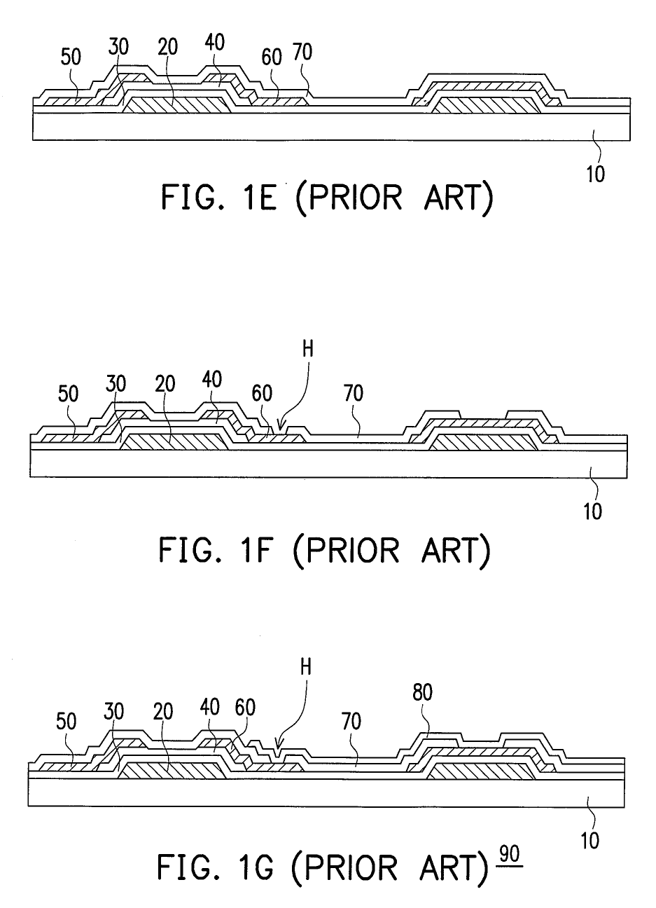

### DESCRIPTION OF EMBODIMENTS

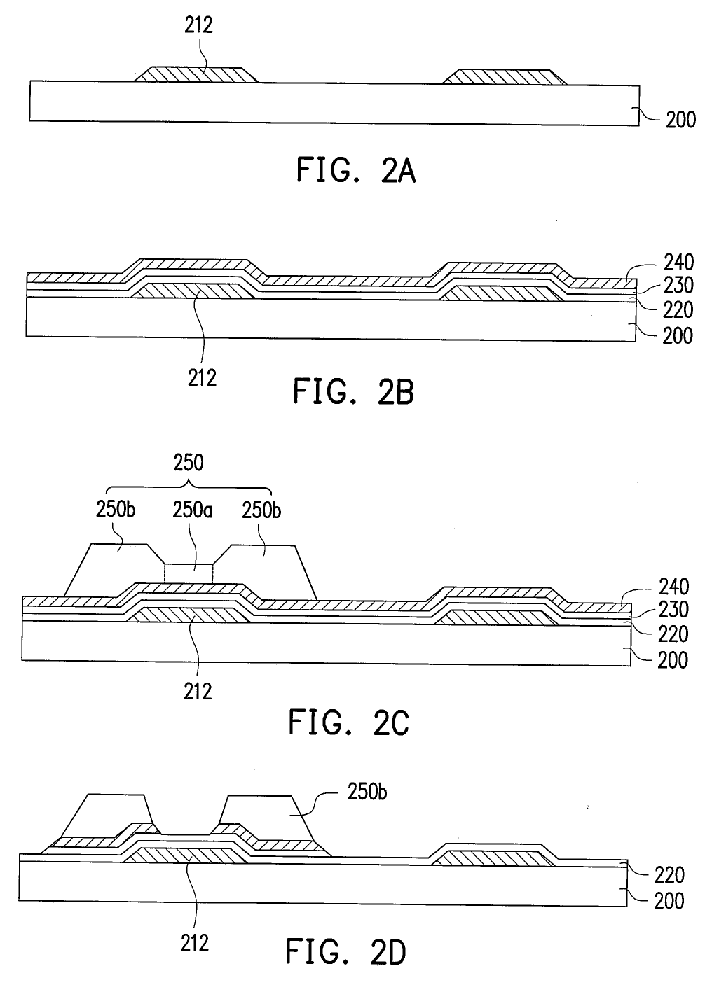

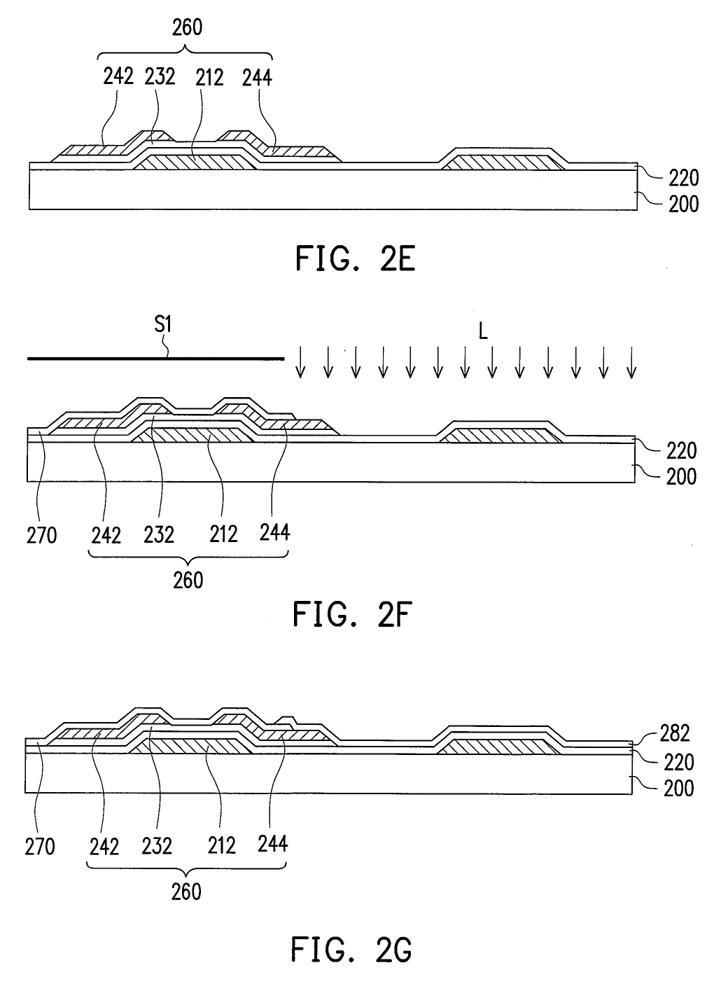

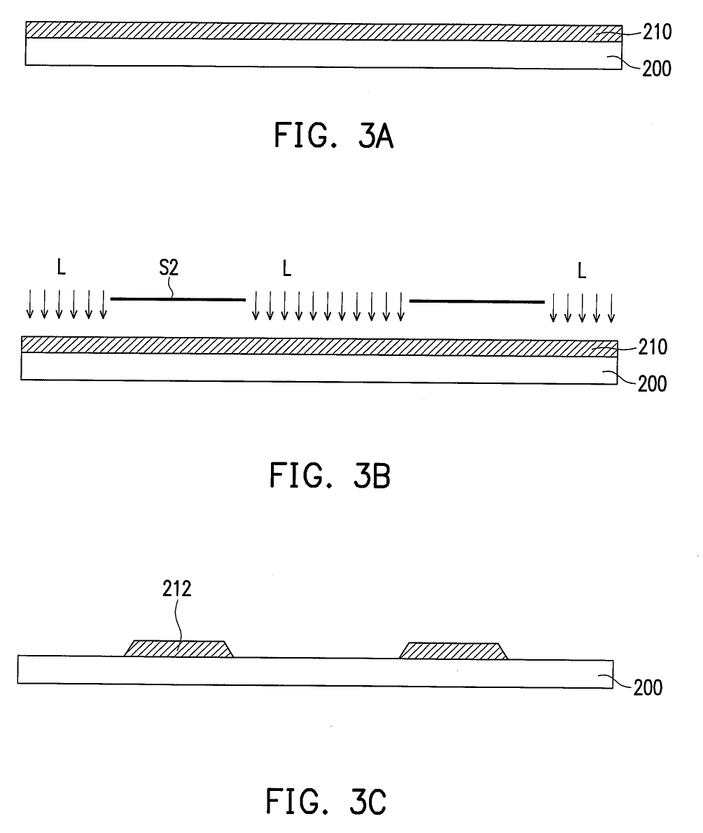

FIGS. 2A to 2G are schematic views illustrating a method of manufacturing a pixel structure according to one embodiment of the present invention. Referring to FIG. 2A, a substrate 200 is provided at first. A material of the substrate 200 includes glass, plastic, and other solid or soft materials. Then, a gate 212 is formed on the substrate 200. According to the present embodiment, a first metal layer 210 (shown in FIG. 3A) can be formed on the substrate 200 at first. Next, the first metal layer 210 is patterned to form the gate 212. In addition, the first metal layer 210 is formed by performing a sputtering process, an evaporation process, or other thin film depositing processes, for example. The first metal layer 210 is patterned by performing photolithography and etching processes, for example.

After that, referring to FIG. 2B, a gate dielectric layer 220 is formed on the substrate 200 to cover the gate 212. The gate dielectric layer 220 is formed by performing a chemical vapor deposition process (CVD) or other suitable thin film depositing processes, for example. A material of the gate dielectric layer 220 includes, for example, silicon oxide, silicon nitride, silicon oxynitride, or other dielectric materials. Thereafter, a semiconductor layer 230 and a second metal layer 240 are formed on the gate dielectric layer 220 sequentially. According to the present embodiment, a material of the semiconductor layer 230 includes, for example, amorphous silicon or other semiconductor materials. A material of the second metal layer 240 includes, for example, aluminum (Al), molybdenum (Mo), titanium (Ti), neodymium (Nd), nitrides thereof such as molybdenum nitride (MoN), titanium nitride (TiN), and stacked layers thereof, the alloy of Al, Mo, Ti and Nd, or other conductive materials.

Referring to FIG. 2C, a photoresist layer 250 is formed on the second metal layer 240 over the gate 212 after the second metal layer 240 is formed. Referring to FIG. 2C, the photoresist layer 250 includes a first photoresist block 250a and a second photoresist block 250b connected with the first photoresist block 250a. The thickness of the first photoresist block 250a is less than the thickness of the second photoresist block 250b. Then, a first etching process is performed on the second metal layer 240 and the semiconductor layer 230 by using the photoresist layer 250 as a mask.

Next, as shown by FIG. 2D, the thickness of the photoresist layer 250 is reduced until the first photoresist block 250a is completely removed, and at the same time, the thickness of the second photoresist block 250b is correspondingly reduced. According the present embodiment, a method of reducing the thickness of the photoresist layer 250 includes performing an ashing process, for example. Referring to FIG. 2D, after the first photoresist block 250a is completely removed, a second etching process is performed on the second metal layer 240 by using the remained second photoresist block 250b as the mask. After that, the remained photoresist layer 250 is removed. According to the present embodiment, the first etching process and the second etching process include, for example, performing a wet etching process, while a dry etching process may be performed in other embodiments instead of the wet etching process. Furthermore, the photoresist layer 250 is removed by performing the wet etching process or an ashing process, for example.

Referring to FIG. 2E, the remained second metal layer 240 (shown in FIG. 2C) constitutes a source 242 and a drain 244. The semiconductor layer 230 (shown in FIG. 2C) constitutes a channel layer 232. The source 242 and the drain 244 are disposed on a portion of the channel layer 232. The gate 212, the channel layer 232, the source 242 and the drain 244 constitute a thin film transistor 260. It should be noted that the channel layer 232, the source 242, and the drain 244 are formed in the present embodiment. Therefore, a process of manufacturing one photo-mask can be eliminated, and thereby the process complexity can be reduced. In addition, the channel layer 232, the source 242 and the drain 244 of the thin film transistor 260 can be formed in the same process such as a half-tone mask process or a gray-tone mask process. According to other embodiments of the present invention, an ohmic contact layer (not shown) is formed on a surface of the semiconductor layer 230 before the second metal layer 240 and the photoresist layer 250 (as shown in FIG. 2C) are formed. Then, a portion of the ohmic contact layer (not shown) is removed by performing the first etching process and the second etching process.

A contact resistance between the semiconductor layer 230 and the second metal layer 240 can be reduced, for example, by forming an N-type doped region on the surface of the semiconductor layer 230 through an ion doping method. Referring to FIG. 2F, a passivation layer 270 is formed on the gate dielectric layer 220 and the thin film transistor 260. According to the present embodiment, a material of the passivation layer 270 includes, for example, silicon nitride or silicon oxide. A method of forming the passivation layer 270 includes depositing the passivation layer 270 entirely on the substrate 200 by performing a physical vapor deposition (PVD) process or the CVD process, for example. Generally, a portion of the passivation layer 270 is removed to expose the drain 244 by performing photolithography and etching processes. However, it should be noted that when the drain 244 is exposed, sides of the semiconductor layer 230 under the drain 244 are exposed at the same time. Due to the fact that an etching rate of the semiconductor layer 230 is faster than the etching rate of a metal material of the drain 244, an undercut is easily formed on the sides of the semiconductor layer 230. Therefore, in a subsequent process of depositing a pixel electrode 282 (shown in FIG. 2G), the pixel electrode 282 (shown in FIG. 2G) may not be connected with the drain 244 because of the undercut at the sides of the semiconductor layer 230, thereby causing a disconnection problem between the drain 244 and the pixel electrode 282 (shown in FIG. 2G).

According to the present invention, a layer ablation process is utilized to remove a portion of the passivation layer 270 for exposing the drain 244. As shown in FIG. 2F, in the laser ablation process, the laser beam L is utilized to irradiate the passivation layer 270 via a first shadow mask S1 to remove the portion of the passivation layer 270 for exposing the drain 244. In detail, the passivation layer 270 irradiated by utilizing the laser beam L absorbs energy of the laser beam L, and therefore ablates from a surface of the thin film transistor 260 while the passivation layer 270 covered by the first shadow mask S1 remains. Then, a portion of the passivation layer over the drain is removed. More specifically, the energy of the laser beam L used for ablating the passivation layer 270 can be in the range from 10 mJ/cm² to 500 mJ/cm², for example. Furthermore, a wavelength of the laser beam can be in the range from 100 nm to 400 nm, for example. Because the laser ablation process does not affect or damage the source 244 and the semiconductor layer 230, when a subsequently deposited pixel electrode 282 (shown in FIG. 2G) is connected with the exposed drain 244, the sides of the drain 244 and the semiconductor layer 230 are still even and smooth. Therefore, the disconnection problem between the pixel electrode 282 (shown in FIG. 2G) and the drain 244 can be effectively avoided.

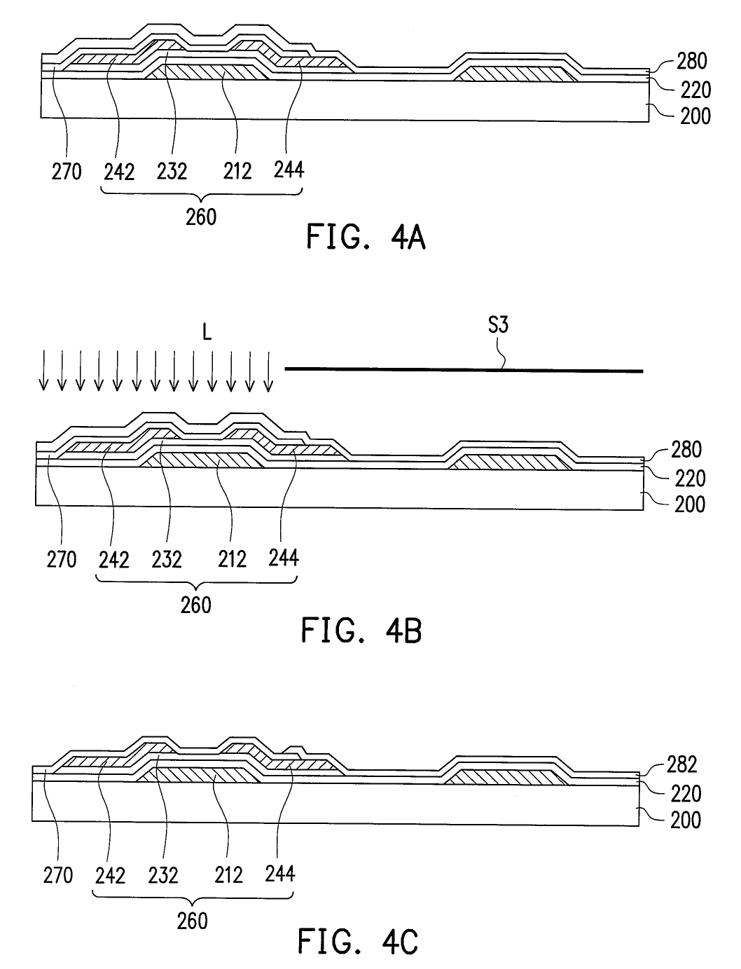

Referring to FIG. 2G, a pixel electrode 282 is then formed on the gate dielectric layer 220, and the pixel electrode 282 is electrically connected with the exposed drain 244. According to the present embodiment, a method of forming the pixel electrode 282 includes, for example, forming a conductive layer 280 (shown in FIG. 4A) on the passivation layer 270 and the drain 244 after the portion of the passivation layer 270 exposed by the first shadow mask S1 is removed. Next, the conductive layer 280 is patterned. Because the passivation layer 270 on the drain 244 and the semiconductor layer 230 are formed by performing the laser ablation process, the disconnection problem can be avoided when connecting the pixel electrode 282 to the exposed drain 244.

It should be noted that the gate 212 can also be formed by performing the laser ablation process. FIGS. 3A to 3C are schematic views illustrating a laser ablation process used for forming a gate. Referring to FIG. 3A, a first metal layer 210 is formed on the substrate 200. Next, a second shadow mask S2 is provided over the first metal layer 210. The second shadow mask S2 exposes a portion of the first metal layer 210. After that, the laser beam L is utilized to irradiate the first metal layer 210 via the second shadow mask S2 for removing the portion of the first metal layer 210, wherein the portion of the first metal layer 210 is exposed by the second shadow mask S2. Finally, as shown in FIG. 3C, the remained first metal layer 210 constitutes the gate 212.

In addition, a method of forming the pixel structure 282 can include performing the laser ablation process. FIGS. 4A to 4C are schematic views illustrating the laser ablation process used for forming the pixel electrode. Referring to FIG. 4A, a conductive layer 280 is formed on the passivation layer 270 and the thin film transistor 260 after a portion of the passivation layer 270 exposed by the first shadow mask S1 is removed. Next, a third shadow mask S3 is provided over the conductive layer 280. The third shadow mask S3 exposes a portion of the conductive layer 280. Then, referring to FIG. 4C, the laser beam L is utilized to irradiate the conductive layer 280 via the third shadow mask S3 for removing the portion of the conductive layer exposed by the third shadow mask S3.

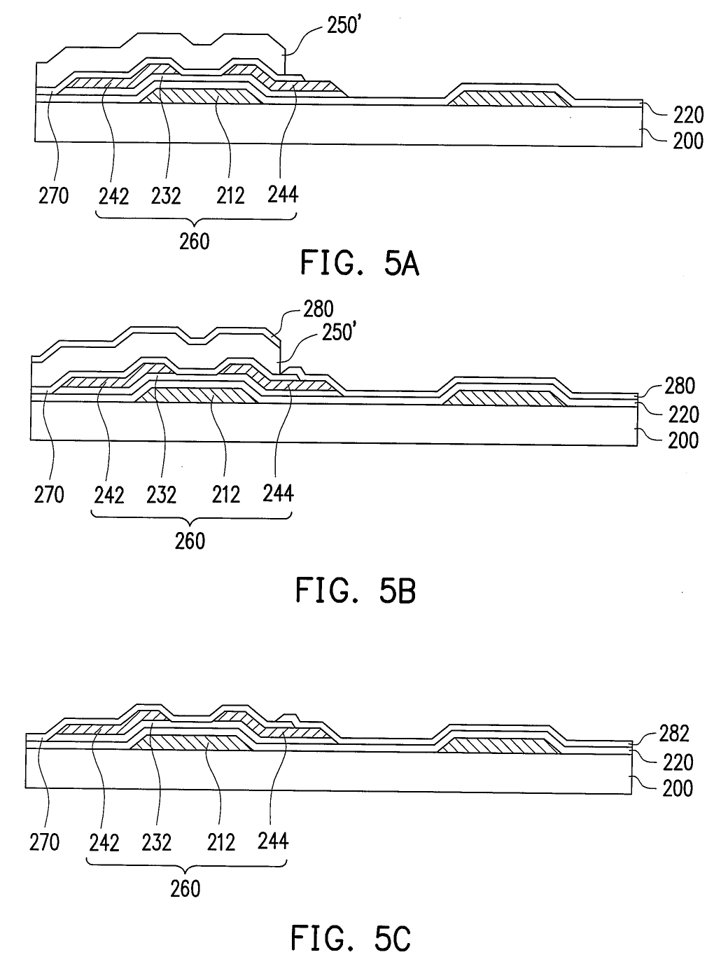

Certainly, according to other embodiments of the present invention, a method of forming the pixel electrode 282 can be illustrated by FIGS. 5A to 5C, for example. Referring to FIG. 5A, a photoresist layer 250′ is formed on the passivation layer 270 after a portion of the passivation layer 270 exposed by the first shadow mask S1 is removed, wherein the photoresist layer 250′ exposes a portion of the drain 244. Referring to FIG. 5B, a conductive layer 280 is formed to cover the passivation layer 270, the drain 244 and the photoresist layer 250′. After that, referring to FIG. 5C, the photoresist layer 250′ is removed, so as to remove the conductive layer 280 thereon together. The remained conductive layer 280 constitutes the pixel electrode 282. A method of forming the conductive layer 280 includes forming an indium zinc oxide (ITO) layer or an indium zinc oxide (IZO) layer by performing a sputtering process. Furthermore, the laser ablation process can be performed by using a digital exposure method. The digital exposure method includes, for example, positioning the laser beam automatically and adjusting the energy of the laser beam to perform the laser ablation process.

In light of the above, in the present invention, the channel layer, the source and the drain are manufactured at the same time. Therefore, compared with the prior art, the present invention is conducive to reducing the process complexity. Moreover, according to the present invention, the passivation layer is formed by irradiation of the laser beam L and is not formed by performing photolithography and etching processes. Therefore, the method for manufacturing the pixel structure according to the present invention has at least the following advantages:

The method for manufacturing the pixel structure provided by the present invention does not require performing a photolithography process for manufacturing the passivation layer. Therefore, compared with a conventional photolithography and etching process (PEP) which needs to be performed with high precision, the present invention is conducive to reducing the process cost of manufacturing the photo-mask.

Furthermore, because the process complexity of manufacturing the pixel structure is simplified, the present invention is conducive to reducing the defects which may occur when manufacturing the pixel structure in the long and complicated PEP, wherein the PEP can include, for example, steps of photoresist coating, soft baking, hard baking, exposure, photolithography, etching, photoresist stripping.

According to the present invention, the method of ablating the portion of the passivation layer by using the laser beam can prevent the drain and the semiconductor layer from being affected or damaged. Therefore, the disconnection problem between the exposed drain and the pixel electrode does not occur when the subsequently deposited pixel structure is connected with the exposed drain.

The method of ablating the portion of the passivation layer by using the laser beam can be used to repair the pixel structure, so as to remove an ITO residue which may remain on the pixel electrode, thereby resolving a short circuit problem between the pixel electrodes and increasing process yield.

Although the present invention has been described with reference to the above embodiments, it will be apparent to one of the ordinary skill in the art that modifications to the described embodiment may be made without departing from the spirit of the present invention. Accordingly, the scope of the present invention will be defined by the attached claims not by the above detailed description.

What is claimed is:

1. A method for manufacturing a pixel structure, comprising:
providing a substrate;
forming a gate on the substrate;
forming a gate dielectric layer on the substrate to cover the gate;
forming a channel layer, a source and a drain on the gate dielectric layer and over the gate, wherein the source and the drain are disposed on a portion of the channel layer, and the gate, the channel layer, the source and the drain constitute a thin film transistor;
forming a passivation layer on the gate dielectric layer and the thin film transistor;
irradiating the passivation layer via a first shadow mask with a laser beam to remove a portion of the passivation layer for exposing the drain; and
forming a pixel electrode on the gate dielectric layer, wherein the pixel electrode is connected with the exposed drain.

2. The method for manufacturing the pixel structure according to claim 1, wherein a method of forming the gate comprises:
forming a first metal layer on the substrate; and
patterning the first metal layer to form the gate.

3. The method for manufacturing the pixel structure according to claim 1, wherein
a method of forming the gate comprises:
forming a first metal layer on the substrate;
providing a second shadow mask over the first metal layer, the second shadow mask exposing a portion of the first metal layer; and
irradiating the first metal layer via the second shadow mask with a laser beam to remove the portion of the first metal layer exposed by the second shadow mask.

4. The method for manufacturing the pixel structure according to claim 1, wherein a method of simultaneously forming the channel layer, the source and the drain comprises:
forming a semiconductor layer on the gate dielectric layer;
forming a second metal layer on the semiconductor layer;
forming a photoresist layer on the second metal layer over the gate, wherein the photoresist layer comprises a first photoresist block and a second photoresist block connected with the first photoresist block, and a thickness of the first photoresist block is less than a thickness of the second photoresist block;
performing a first etching process on the second metal layer and the semiconductor layer by using the photoresist layer as a mask;
reducing the thickness of the photoresist layer until the first photoresist block is removed completely; and
performing a second etching process on the second metal layer by using the remained second photoresist block as the mask, such that the remained second metal layer constitutes the source and the drain while the semiconductor layer constitutes the channel layer.

5. The method for manufacturing the pixel structure according to claim 4, wherein a method of forming the channel layer, the source and the drain further comprises:
forming an ohmic contact layer on a surface of the semiconductor layer after the semiconductor layer is formed; and
removing the ohmic contact layer uncovered by the second photoresist block by performing the first etching process and the second etching process.

6. The method for manufacturing the pixel structure according to claim 4, wherein a method of reducing the thickness of the photoresist layer comprises performing an ashing process.

7. The method for manufacturing the pixel structure according to claim 1, wherein a method of forming the pixel electrode comprises:
forming a conductive layer on the passivation layer and the thin film transistor after the portion of the passivation layer exposed by the first shadow mask is removed; and
patterning the conductive layer.

8. The method for manufacturing the pixel structure according to claim 7, wherein a method of forming the conductive layer comprises forming an indium tin oxide layer or an indium zinc oxide layer by performing a sputtering process.

9. The method for manufacturing the pixel structure according to claim 1, wherein a method of forming the pixel electrode comprises:
forming a conductive layer on the passivation layer and the thin film transistor after the portion of the passivation layer exposed by the first shadow mask is removed;
providing a third shadow mask over the conductive layer, the third shadow mask exposing a portion of the conductive layer; and
irradiating the conductive layer via the third shadow mask with a laser beam to remove the portion of the conductive layer exposed by the third shadow mask.

10. The method for manufacturing the pixel structure according to claim 9, wherein a method of forming the conductive layer comprises forming an indium tin oxide layer or an indium zinc oxide layer by performing a sputtering process.

11. The method for manufacturing the pixel structure according to claim 1, a method of forming the pixel electrode comprising:
forming a photoresist layer on the passivation layer after the portion of the passivation layer exposed by the first shadow mask is removed, wherein the photoresist layer exposes a portion of the drain;
forming a conductive layer to cover the passivation layer, the drain and the photoresist layer; and
removing the photoresist layer, so as to remove the conductive layer on the photoresist layer together.

12. The method for manufacturing the pixel structure according to claim 11, wherein a method of forming the conductive layer comprises forming an indium tin oxide layer or an indium zinc oxide layer by performing a sputtering process.

13. The method for manufacturing the pixel structure according to claim 1, wherein an energy of the laser beam is in the range from 10 mJ/cm² to 500 mJ/cm².

14. The method for manufacturing the pixel structure according to claim 1, wherein a wavelength of the laser beam is in the range from 100 nm to 400 nm.

15. A method for manufacturing a pixel structure, comprising:
providing a substrate;
forming a thin film transistor on the substrate, wherein the thin film transistor includes a drain;
forming a passivation layer on the thin film transistor;
irradiating the passivation layer via a first shadow mask with a laser beam to remove a portion of the passivation layer for exposing the drain; and
forming a pixel electrode on the gate dielectric layer, wherein the pixel electrode is connected with the exposed drain.
